(19) United States
(12) Patent Application Publication
(10) Pub. No.: US 2025/0176324 A1
(43) Pub. Date: May 29, 2025

(54) COVER GLASS WITH OUTER FRAME, SEMICONDUCTOR LIGHT EMITTING DEVICE, AND SEMICONDUCTOR LIGHT RECEIVING DEVICE

(71) Applicant: AGC Inc., Tokyo (JP)

(72) Inventors: Nanako NISHIMOTO, Tokyo (JP); Ryota MURAKAMI, Tokyo (JP)

(73) Assignee: AGC Inc., Tokyo (JP)

(21) Appl. No.: 19/038,957

(22) Filed: Jan. 28, 2025

Related U.S. Application Data
(63) Continuation of application No. PCT/JP2023/025953, filed on Jul. 13, 2023.

(30) Foreign Application Priority Data
Jul. 29, 2022 (JP) 2022-122179

(51) Int. Cl. H10H 20/85; B81B 7/00; C03C 14/00; C03C 27/10; C04B 35/10; C04B 35/195; C04B 37/00; H01S 5/02257

(52) U.S. Cl. CPC H10H 20/8506; B81B 7/0067; C03C 14/004; C03C 27/10; C04B 35/10; C04B 35/195; C04B 37/003; H01S 5/02257; C03C 2214/04; C04B 2235/3217; C04B 2235/3481; C04B 2235/365; C04B 2235/447; C04B 2237/10; C04B 2237/341; C04B 2237/343

(57) ABSTRACT

The present invention relates to a cover glass with an outer frame including: a flat glass having a first main surface and a second main surface that are opposite sides; and an outer frame bonded to the first main surface of the flat glass via a glass adhesive layer, in which the outer frame is made of a glass ceramic in which a filler is dispersed in a borosilicate glass, the borosilicate glass and the filler both contain aluminum oxide, the filler has a volume fraction of 40% to 65% in the glass ceramic, the aluminum oxide contained in the filler has a volume fraction of 10% to 65% in the glass ceramic, and an absolute value of a difference in average thermal expansion coefficient at 50° C. to 350° C. between the flat glass and the outer frame is 20×10⁻⁷/° C. or less.

### CROSS-REFERENCE TO RELATED APPLICATIONS

This is a continuation of International Application No. PCT/JP2023/025953 filed on Jul. 13, 2023, and claims priority from Japanese Patent Application No. 2022-122179 filed on Jul. 29, 2022, the entire contents of which are incorporated herein by reference.

### TECHNICAL FIELD

The present invention relates to a cover glass with an outer frame. The present invention also relates to a semiconductor light emitting device and a semiconductor light receiving device that are hermetically sealed using the above cover glass with an outer frame.

### BACKGROUND ART

Devices using a light emitting diode (LED) are used for a wide range of applications, such as a backlight for mobile phones and a large liquid crystal display television, and for illumination applications.

For example, in the case of a light emitting device using a light emitting diode that emits visible light (visible light LED), a configuration in which an LED chip is placed on a flat substrate such as aluminum nitride and sealed using a resin-based member is often used.

In respect to this, light emitting devices using a light emitting diode that emits ultraviolet light (UV-LED), a laser diode (LD), a vertical cavity surface emitting laser (VCSEL), or the like require hermetic sealability. A diffuser is also required in the VCSEL.

Therefore, these light emitting devices are required to have a shape in which a cover glass is attached with an outer frame. It is possible to provide the outer frame on a substrate such as aluminum nitride, and it is more practical to provide the outer frame on the cover glass in terms of cost.

Not only the above light emitting devices but also a light receiving device such as a sensor may require hermetic sealability. For example, there is a device called a micro electro mechanical system (MEMS), which is a device in which electrical circuits and fine mechanical structures are integrated on a single substrate. An example of the substrate used in the MEMS is a silicon substrate.

Similar to the light emitting devices, the light receiving device is also required to have a shape in which a cover glass is attached with an outer frame. It is possible to provide the outer frame on a substrate such as silicon, and it is more practical to provide the outer frame on the cover glass in terms of cost.

The simplest method for producing an cover glass with an outer frame is to prepare a cover glass and a glass for the outer frame separately and then adhere the two together with a resin-based member. However, the adhesion using a resin-based member, which is an organic substance, does not provide the hermetic sealability.

Examples of a method for achieving the hermetic sealability include a method of forming a portion to be the outer frame by directly wet etching the glass. However, it is not possible to obtain perpendicularity between a flat portion and the portion to be the outer frame, and it is also difficult to prepare a deep frame. In order to obtain the hermetic sealability while maintaining the perpendicularity, a method of directly bonding the flat glass and the glass to be the outer frame, such as diffusion bonding or room temperature bonding, may be used.

On the other hand, since the direct bonding is very high in cost, techniques of providing an outer frame on a glass substrate have been studied and proposed from various angles.

For example, Patent Literature 1 discloses a synthetic quartz glass cavity obtained by pasting a raw material synthetic quartz glass substrate, which has a plurality of through holes formed by sandblasting, to another raw material synthetic quartz glass substrate and adhering the two substrates at 1000° C. to 1200° C.

Patent Literature 2 discloses an anti-reflective glass with a frame in which a silicon substrate having through holes formed therein by reactive ion etching is used as a frame member, and is superimposed on a borosilicate glass as a flat member, followed by subjecting to anodic bonding.

Patent Literature 3 discloses a glass sealing material in which a glass plate and a glass piece are sandwiched between a base mold and a facing mold and bonded to each other by welding using a hot press.

### CITATION LIST

### Patent Literature

Patent Literature 1: JP2020-21937A
Patent Literature 2: JP5646981B
Patent Literature 3: JP2013-222522A
Patent Literature 4: WO2022/138519

### SUMMARY OF INVENTION

### Technical Problem

However, when heat is applied at a temperature higher than a glass softening point of the glass material used, as in the methods disclosed in Patent Literatures 1 and 3, the surface of the glass is damaged, raising concerns about reliability. When thermal expansion coefficients of the flat member and the frame member are different, as in the method disclosed in Patent Literature 2, there is a risk of cracks occurring in a glass as the flat member. In addition, anodic bonding is also high in cost.

On the other hand, the inventors of the present invention have proposed a novel cover glass with an outer frame in which an outer frame in which a specific glass ceramic is used is directly bonded to a flat glass, as disclosed in Patent Literature 4. Accordingly, when the outer frame is set to a certain height or more, it is possible to achieve both perpendicularity and adhesion to the cover glass, and it is also possible to reduce damage and cracks on the surface of the flat glass.

However, as a result of further investigation by the inventors of the present invention, it has been found that in the case where a flat glass and an outer frame are directly bonded to each other, improvements are desired in terms of chemical resistance.

Therefore, an object of the present invention is to provide an cover glass with an outer frame that achieves both adhesion between an outer frame and a flat glass and perpendicularity of the outer frame, that has reduced damage and cracks on the surface of the flat glass, and that has favorable chemical resistance.

### Solution to Problem

In order to solve the above problems, one aspect of a cover glass with an outer frame according to the present embodiment is as follows.

A cover glass with an outer frame including:
a flat glass having a first main surface and a second main surface that are opposite sides; and
an outer frame bonded to the first main surface of the flat glass via a glass adhesive layer, in which
the outer frame is made of a glass ceramic in which a filler is dispersed in a borosilicate glass,
the borosilicate glass and the filler both contain aluminum oxide,
the filler has a volume fraction of 40% to 65% in the glass ceramic,
the aluminum oxide contained in the filler has a volume fraction of 10% to 65% in the glass ceramic, and
an absolute value of a difference in average thermal expansion coefficient at 50° C. to 350° C. between the flat glass and the outer frame is 20×10⁴/° C. or less.

In addition, an aspect of a semiconductor light emitting device according to the present embodiment is as follows.

A semiconductor light emitting device including:
a cover glass with an outer frame;
a substrate; and;
a light emitting element provided on the substrate, in which
the cover glass with an outer frame is integrated with the substrate via a sealing material layer made of a metal film in the cover glass with an outer frame and a gold-tin ring, to hermetically seal the light emitting element.

Note that, the cover glass with an outer frame is the cover glass with an outer frame described above as one aspect, and is an cover glass with an outer frame further including a sealing material layer made of a metal film on a surface of the outer frame that is opposite to a surface facing the flat glass, in which the metal film includes an Ag layer or an Au layer on an outermost surface thereof.

An aspect of a semiconductor light receiving device according to the present embodiment is as follows.

A semiconductor light receiving device including:
a cover glass with an outer frame
a substrate; and;
a light receiving element provided on the substrate, in which
the cover glass with an outer frame is integrated with the substrate via a sealing material layer made of a metal film in the cover glass with an outer frame and a gold-tin ring, to hermetically seal the light receiving element.

### Advantageous Effects of Invention

With the cover glass with an outer frame according to the present invention, both adhesion between the outer frame and the flat glass and perpendicularity of the outer frame can be achieved, and damage to the cover glass caused by energy of a light source such as a UV-LED or a laser diode (LD) or energy of light received by a sensor can be prevented. In addition, since there is no heat damage and cracks on the surface of the flat glass, it has very high reliability as a cover glass with an outer frame. Such reliability is based on the viewpoint of resistance to high temperature and high humidity, resistance to heat shock, and perpendicularity, in addition to hermetic sealability. In addition, the cover glass with an outer frame has very favorable chemical resistance and is therefore excellent in durability. From these viewpoints, it is possible to obtain an excellent semiconductor light emitting device or semiconductor light receiving device that is hermetically sealed using the cover glass with an outer frame according to the present invention.

### BRIEF DESCRIPTION OF DRAWINGS

FIG. 1 is a schematic cross-sectional view illustrating an example of the cover glass with an outer frame according to the present embodiment.

FIG. 2 is a schematic cross-sectional view illustrating an example of the cover glass with an outer frame according to the present embodiment.

FIG. 3 is a schematic cross-sectional view illustrating an example of the cover glass with an outer frame according to the present embodiment.

FIG. 4 is a schematic cross-sectional view illustrating an example of the cover glass with an outer frame according to the present embodiment.

FIG. 5A is a schematic cross-sectional view illustrating an example of the cover glass with an outer frame according to the present embodiment in which an anti-reflective film is provided on both main surfaces of a flat glass.

FIG. 5B is a schematic cross-sectional view illustrating an example of the cover glass with an outer frame according to the present embodiment in which a flat glass includes a light diffusing portion on a first main surface and an anti-reflective film is provided on both main surfaces.

### DESCRIPTION OF EMBODIMENTS

Hereinafter, the present invention is described in detail, but the present invention is not limited to the following embodiments, and can be freely modified and implemented without departing from the gist of the present invention.

In the present description, “to” indicating a numerical range is used in the sense of including the numerical values set forth before and after the “to” as a lower limit value and an upper limit value.

In the present description, an “average thermal expansion coefficient” or a “thermal expansion coefficient” refers to a value measured, using a Dilatometer TD5000SA manufactured by NETZSCH Japan, as an average value of the rate of elongation per degree Celsius during heating at a heating rate of 5° C./min in the range of 50° C. to 350° C.

In the present description, a content in a glass matrix is a content in components excluding a filler from a glass ceramic, and is expressed in vol %. Contents of various components contained in the glass matrix are expressed as mass % based on oxides. In addition, “mass %” is synonymous with “wt %”.

Further, a content of the filler in the glass ceramic is a content excluding a glass component, i.e., the glass matrix, from the glass ceramic, and is a value expressed in vol %. The vol % is a value calculated based on the mass % and a specific gravity of each component. When the mass % of the glass matrix is M1 and the specific gravity thereof is ρ1, and the mass % of the filler is M2 and the specific gravity thereof is ρ2, the vol % of the glass matrix and the vol % of the filler can be calculated based on the contents expressed in mass % using the following equations.

$$\begin{matrix}Vol \% of glass matrix = ( M 1 / ρ1 ) / ( M 1 / ρ1 + M 2 / ρ2 ) \\ Vol \% of filler = ( M 2 / ρ2 ) / ( M 1 / ρ1 + M 2 / ρ2 )\end{matrix}$$

In addition, the vol % of the glass ceramic after sintering can be calculated based on the mass % based on oxides and the specific gravity obtained by energy dispersive X-ray analysis (EDX) or inductively coupled plasma emission spectrometry (JCP).

<Cover Glass with Outer Frame>

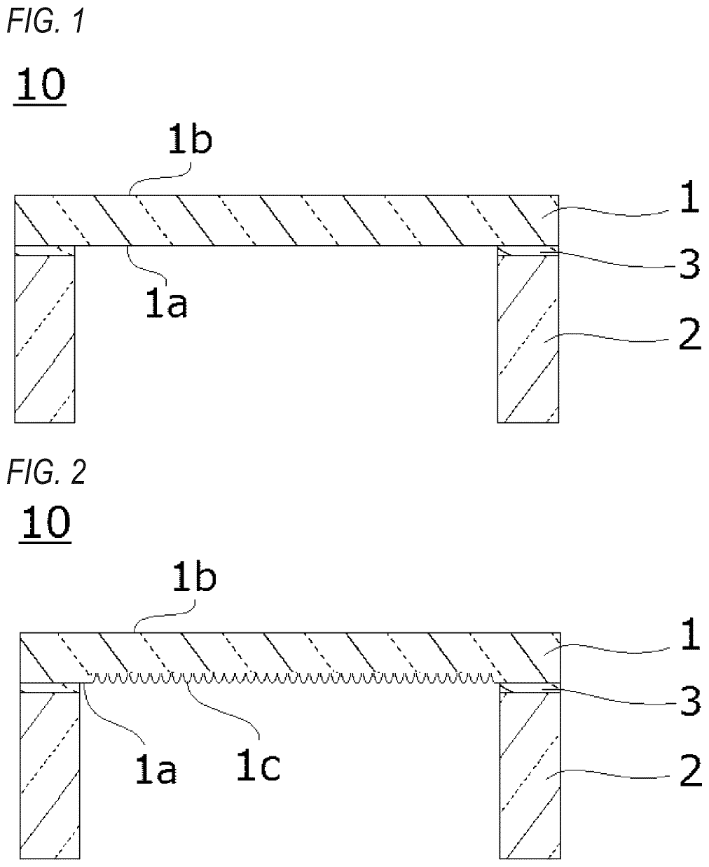

As shown in FIG. 1, a cover glass with an outer frame 10 according to the present embodiment includes an outer frame 2 bonded onto a first main surface 1a of a flat glass 1 via a glass adhesive layer 3. The outer frame 2 is bonded to the flat glass 1 along an outer edge.

The outer frame 2 is made of a glass ceramic in which a filler is dispersed in a borosilicate glass as a glass matrix, and the borosilicate glass and the filler both contain aluminum oxide.

The filler has a volume fraction of 40% to 65% in the glass ceramic, and the aluminum oxide contained in the filler has a volume fraction of 10% to 65% in the glass ceramic.

An absolute value of a difference in average thermal expansion coefficient at 50° C. to 350° C. between the flat glass and the outer frame is 20×10⁻⁷/° C. or less.

### <<Flat Glass>>

The flat glass 1 includes the first main surface 1a and a second main surface 1b that are opposite sides, and the outer frame 2 is bonded to the first main surface 1a via the glass adhesive layer 3.

The flat glass 1 is not particularly limited as long as the absolute value of the difference in average thermal expansion coefficient at 50° C. to 350° C. between the outer frame 2 and the flat glass 1 is 20×10⁻⁷/° C. or less. The absolute value of the difference is preferably 20×10⁻⁷/° C. to 99×10⁻⁷/° C., more preferably 25×10⁻⁷/° C. to 90×10⁻⁷/° C., and still more preferably 30×10⁻⁷/° C. to 80×10⁻⁷/° C., from the viewpoint of being close to a thermal expansion coefficient of a substrate on which the cover glass with an outer frame 10 is to be mounted. Here, the lower limit is preferably 20×10⁻⁷/° C. or more, more preferably 25×10⁻⁷/° C. or more, and still more preferably 30×10⁻⁷/° C. or more. In addition, the upper limit is preferably 99×10⁻⁷/° C. or less, more preferably 90×10⁻⁷/° C. or less, and still more preferably 80×10⁻⁷/° C. or less.

The flat glass 1 is preferably has a glass transition point Tg higher than a softening point Ts of the glass adhesive layer 3. Specifically, the glass transition point Tg of the flat glass 1 is more preferably 500° C. or higher, still more preferably 515° C. or higher, and even more preferably 520° C. or higher, from the viewpoint of preventing an insulating property from being inhibited due to an increase in carbon residues during firing, and from the viewpoint of heat resistance when sealing with a substrate. The higher the glass transition point Tg, the more preferred. Note that, the glass transition point Tg of the flat glass 1 is a temperature at the first inflection point in a differential thermal analysis (DTA) chart obtained by DTA.

A glass softening point Ts of the flat glass 1 is preferably 700° C. or higher, more preferably 715° C. or higher, and still more preferably 730° C. or higher, from the viewpoint of preventing damage to the surface of the flat glass. The higher the glass softening point Ts, the more preferred. Note that, the glass softening point Ts of the flat glass 1 is a temperature at the fourth inflection point in the DTA chart.

Specifically, the flat glass 1 is preferably transparent in a visible to near infrared range, and for example, a soda lime glass, a borosilicate glass, an aluminosilicate glass, a silica glass, and a sapphire glass can be used. A borosilicate glass is preferred from the viewpoint of ease of processing. In addition, a silica glass is preferred from the viewpoint of durability and transmissibility.

A thickness of the flat glass 1 is not particularly limited, and is preferably 200 μm to 1.5 mm, more preferably 250 μm to 1.2 mm, and still more preferably 300 μm to 1.1 mm, Here, the thickness of the flat glass is preferably 200 μm or more, more preferably 250 μm or more, and still more preferably 300 μm or more, from the viewpoint of the durability. On the other hand, the thickness of the flat glass 1 is preferably 1.5 mm or less, more preferably 1.2 mm or less, and still more preferably 1.1 mm or less, from the viewpoint of the transmissibility and a weight.

The flat glass 1 may include a light diffusing portion on at least one of the first main surface 1a or the second main surface 1b, and may include a light diffusing portion 1c on the first main surface 1a, as shown in FIG. 2. The light diffusing portion 1c is preferably formed by directly processing the first main surface 1a of the flat glass 1. Note that, a separate light diffusing layer may be provided instead of the light diffusing portion formed by direct processing, and at this time, the light diffusing layer is preferably made of an inorganic material from the viewpoint of hermetic sealability.

The light diffusing portion 1c formed by directly processing the flat glass 1 is preferred from the viewpoint of reducing a loss due to interfacial reflection and preventing peeling between layers, compared to the case where a separate light diffusing layer is formed on the first main surface 1a of the flat glass 1.

From the viewpoint of adhesion between the flat glass 1 and the outer frame 2, the light diffusing portion 1c is preferably formed on the first main surface 1a of the flat glass 1, inside a region of the flat glass 1 where the outer frame 2 is bonded via the glass adhesive layer 3. In the case of performing such direct processing, as the flat glass, for example, EN-A1 (product name), M100 (product name), and M130 (product name) manufactured by AGC Inc., or TEMPAX (registered trademark) and D263 (registered trademark) manufactured by Schott can be suitably used, but are not limited to these.

It is preferable that the light diffusing portion 1c include a plurality of lenses, it is more preferable that a boundary between adjacent lenses be sharp, and it is still more preferable that the lenses be disposed without gaps at least in an effective region in the first main surface 1a of the flat glass 1.

### <<Outer Frame>>

The outer frame 2 is made of a glass ceramic in which a filler is dispersed in a borosilicate glass.

When a borosilicate glass is contained as the glass matrix, chemical resistance of the glass ceramic is greatly improved.

The inventors of the present invention have found that when the borosilicate glass and the filler both contain aluminum oxide, wettability between the borosilicate glass as a glass matrix and the filler is improved, and sinterability is improved. Accordingly, the hermetic sealability using the cover glass with an outer frames is very favorable.

The borosilicate glass is a glass having a glass composition containing boron oxide (B₂O₃) and silicon dioxide (SiO₂). When boron oxide is contained, a glass softening point Ts of the glass ceramic is lowered. In addition, silicon dioxide is a component constituting a glass.

A content of boron oxide in the glass matrix constituting the glass ceramic is not particularly limited, and is, for example, preferably 5 mass % to 50 mass %, more preferably 10 mass % to 30 mass %, and still more preferably 15 mass % to 20 mass %. Here, the lower limit of the content of boron oxide is preferably 5 mass % or more, more preferably 10 mass % or more, and still more preferably 15 mass % or more. On the other hand, the content of boron oxide is preferably 50 mass % or less, more preferably 30 mass % or less, and still more preferably 20 mass % or less, from the viewpoint of preventing a decrease in weather resistance of the flat glass 1.

A content of silicon dioxide in the glass matrix constituting the glass ceramic is not particularly limited, and is, for example, preferably 30 mass % to 85 mass %, more preferably 40 mass % to 80 mass %, and still more preferably 45 mass % to 75 mass %. Here, the lower limit of the content of silicon dioxide is preferably 30 mass % or more, more preferably 40 mass % or more, and still more preferably 45 mass % or more, from the viewpoint of weather resistance. On the other hand, the content of silicon dioxide is preferably 85 mass % or less, more preferably 80 mass % or less, and still more preferably 75 mass % or less, from the viewpoint of preventing the glass softening point Ts from being too high.

A content of aluminum oxide in the glass matrix constituting the glass ceramic is not particularly limited, and is, for example, preferably 0.5 mass % to 25 mass %, more preferably 1 mass % to 20 mass %, and still more preferably 1.5 mass % to 17 mass %. Here, the lower limit of the content of aluminum oxide is preferably 0.5 mass % or more, more preferably 1 mass % or more, and still more preferably 1.5 mass % or more, from the viewpoint of obtaining favorable sinterability. On the other hand, the content of aluminum oxide is preferably 25 mass % or less, more preferably 20 mass % or less, and still more preferably 17 mass % or less, from the viewpoint of preventing ease of devitrification and preventing the glass softening point Ts from being too high.

Note that, aluminum oxide in the glass matrix is distinct from aluminum oxide as a filler. That is, the content of aluminum oxide as a glass composition is excluded from a content of an inorganic powder containing aluminum oxide as a filler.

The borosilicate glass may contain CeO₂, RO, R′₂O, R″₂O₃, and R′″O₂, in addition to SiO₂, B₂O₃, and Al₂O₃. Here, in the present description, R is at least one selected from the group consisting of Zn, Ba, Sr, Mg, Ca, Fe, Mn, Cr, Sn, and Cu. R′ is at least one selected from the group consisting of Li, Na, K, Cs, and Cu. R″ is at least one selected from Fe and La. R″′ is at least one selected from the group consisting of Zr, Ti, and Sn.

Among the above, the glass matrix preferably further contains, for example, ZnO, K₂O, and Na₂O.

More specifically, as the borosilicate glass, for example, a glass containing 50 mass % to 70 mass % of SiO₂, 15 mass % to 20 mass % of B₂O₃, 2 mass % to 15 mass % of Al₂O₃, and 5 mass % to 25 mass % of CaO is suitably used.

Hereinafter, the components in the borosilicate glass other than boron oxide (B₂O₃), silicon dioxide (SiO₂), and aluminum oxide (Al₂O₃) are described.

CeO₂ is a component that stabilizes a color tone of a glass powder after glass raw materials are melted and vitrified. On the other hand, when CeO₂ is added in excess, there is a risk that crystallization occurs easily and it is difficult to obtain a stable glass powder.

The component represented by RO, including CaO, is a component that has an effect in stabilizing the glass and that prevents crystallization. On the other hand, when RO is added in excess, there is a risk that the glass softening point Ts is too high.

The components represented by R′₂O, including K₂O and Na₂O, is a component that lowers the glass softening point Ts. The smaller the atomic number of the element, the greater the effect. However, when the content of the element having a smaller atomic number increases, there is a risk that the insulating property of the glass decreases and the reliability is impaired.

The components represented by R″₂O₃ is a component that has an effect in stabilizing the glass and preventing crystallization, and that improve chemical durability of the glass. On the other hand, when R″₂O₃ is added in excess, there is a risk that the glass softening point Ts is too high.

The components represented by R′″O₂ is a component that supplies oxygen during bonding. On the other hand, when R″O₂ is added in excess, there is a risk of foaming during bonding.

A glass softening point Ts of the borosilicate glass is, for example, preferably 700° C. to 1000° C., more preferably 750° C. to 900° C., and still more preferably 800° C. to 850° C. Here, the glass softening point Ts of the borosilicate glass is preferably 1000° C. or lower, more preferably 900° C. or lower, and still more preferably 850° C. or lower, from the viewpoint of the sinterability of the glass ceramic. In addition, the glass softening point Ts of the borosilicate glass is preferably 700° C. or higher, more preferably 750° C. or higher, and still more preferably 800° C. or higher, from the viewpoint of the heat resistance. Note that, the glass softening point Ts of the borosilicate glass is a temperature at the fourth inflection point in the DTA chart of the glass alone.

The filler in the glass ceramic is dispersed in the borosilicate glass as a glass matrix. The filler contains aluminum oxide, and accordingly, the wettability between the filler and the glass component in the glass ceramic is improved, and the sinterability is improved.

The volume fraction of the filler in the glass ceramic is 40% to 65%, preferably 41% to 63%, and more preferably 42% to 61%. Here, the volume fraction is 40% or more, preferably 41% or more, and more preferably 42% or more, from the viewpoint of providing the glass ceramic with strength required for the outer frame 2 and maintaining perpendicularity to the flat glass 1. In addition, the volume fraction is 65% or less, preferably 63% or less, and more preferably 61% or less, from the viewpoint of realizing favorable sinterability of the outer frame 2 and realizing favorable adhesion when bonding the glass ceramic to the flat glass 1 via the glass adhesive layer.

Note that, in the case where an inorganic powder other than aluminum oxide is also contained as a filler, that is, in the case where two or more kinds of inorganic powders are contained, the above volume fraction is the total volume fraction thereof.

The volume fraction of aluminum oxide contained in the filler in the glass ceramic is 10% to 65%, preferably 11% to 63%, and more preferably 12% to 61%. Here, the volume fraction is 10% or more, preferably 11% or more, and more preferably 12% or more, from the viewpoint of the wettability between the filler and the glass component in the glass matrix and the strength. In addition, the filler may contain only an inorganic powder of aluminum oxide, that is, the volume fraction is 65% or less, preferably 63% or less, and more preferably 61% or less.

The filler may contain an inorganic powder other than aluminum oxide. Examples of such an inorganic powder include a negative thermal expansion filler and a low thermal expansion filler.

The negative thermal expansion filler is a filler that has a thermal expansion coefficient that is a negative value, i.e., less than 0/° C. The negative thermal expansion filler is suitable from the viewpoint of controllability of the thermal expansion coefficient of the outer frame 2 made of a glass ceramic.

Examples of the negative thermal expansion filler include zirconium phosphate having a thermal expansion coefficient of −20×10⁻⁷/° C., β-eucryptite (Li₂O·Al₂O₃·2SiO₂) having a thermal expansion coefficient of −50×10⁻⁷/° C., and zirconium tungstate (ZrW₂O₈) having a thermal expansion coefficient of −7×10⁻⁷/° C.

The low thermal expansion filler is a filler having a thermal expansion coefficient of 0 to 40×10⁻⁷/° C. Examples of the low thermal expansion filler include zirconium oxide, silicon dioxide, and a mixture thereof. Examples of a mixture includes cordierite (2MgO·2Al₂O₃·5SiO₂) which is a mixture of magnesium oxide, aluminum oxide, and silicon dioxide as the low thermal expansion filler. Since cordierite contains aluminum oxide, even in the case where the filler in the present embodiment is made of only cordierite, the filler still contains aluminum oxide.

The filler is an inorganic powder, a shape thereof is not particularly limited, and examples thereof include spherical, flat, scaly, and fibrous.

A size of the inorganic powder is not particularly limited, and for example, a 50% particle diameter (D₅₀) is preferably 0.5 μm to 10 μm, and more preferably 1 Lim to 9 μm. Here, the lower limit of the 50% particle diameter is preferably 0.5 μm or more, and more preferably 1 μm or more, and the upper limit of the 50% particle diameter is preferably 10 μm or less, and more preferably 9 Lm or less. The 50% particle diameter is a volume-based cumulative 50% diameter measured using a laser diffraction/scattering particle size distribution measuring device.

The glass ceramic constituting the outer frame has the above filler dispersed in the above glass matrix.

The average thermal expansion coefficient of the outer frame made of a glass ceramic at 50° C. to 350° C. is not particularly limited as long as the absolute value of the difference in average thermal expansion coefficient between the outer frame and the flat glass is 20×10⁻⁷/° C. or less. The average thermal expansion coefficient of the outer frame is preferably 15×10⁻⁷/° C. to 90×10⁻⁷/° C. or less, and although it varies depending on the thermal expansion coefficient of the flat glass 1, it is more preferably 20×10⁻⁷/° C. to 85×10⁻⁷/° C., and still more preferably 25×10⁻⁷/° C. to 80×10⁻⁷/° C., from the viewpoint of being close to the thermal expansion coefficient of the substrate on which the cover glass with an outer frame 10 is to be mounted. Here, the lower limit of the thermal expansion coefficient is preferably 15×10⁻⁷/° C. or more, more preferably 20×10⁻⁷/° C. or more, and still more preferably 25×10⁻⁷/° C. or more. In addition, the upper limit of the thermal expansion coefficient is preferably 90×10⁻⁷/° C. or less, more preferably 85×10⁻⁷/° C. or less, and still more preferably 80×10⁻⁷/° C. or less.

The glass ceramic forming the outer frame 2 in the present embodiment is configured such that the absolute value of the difference in average thermal expansion coefficient at 50° C. to 350° C. between the flat glass 1 and the outer frame 2 is 20×10⁻⁷/° C. or less. Accordingly, when the outer frame 2 is bonded to the flat glass 1 via the glass adhesive layer, damage and cracks to the flat glass 1 due to expansion mismatch can be prevented.

The absolute value of the difference in the average thermal expansion coefficient is 20×10⁻⁷/° C. or less, preferably 18×10⁻⁷/° C. or less, and more preferably 15×10⁻⁷/° C. or less. The closer to 0/° C., the more preferred.

A maximum height roughness Rz of a surface of the outer frame 2 that is opposite to a surface facing the flat glass 1 is preferably 5 μm or less, more preferably 4.5 μm or less, and still more preferably 4 μm or less, from the viewpoint of adhesion to a substrate to be equipped with a light emitting element or a light receiving element. Since the maximum height roughness Rz of the glass ceramic obtained by firing a glass ceramic precursor is generally about 10 μm, the maximum height roughness Rz can be reduced to 5 μm or less by performing a flattening step such as polishing.

Note that, in the present description, the maximum height roughness Rz is an index of surface roughness, is a sum of the height of the highest peak and the depth of the deepest valley in a contour curve of the reference length, and is determined in accordance with JIS B 0601:2001. Specifically, the maximum height roughness Rz is a value obtained by measuring a measurement length of 3 mm with a surface roughness and contour shape measuring instrument SURFCOM at a cutoff wavelength of 0.8 mm.

The outer frame 2 is preferably bonded perpendicularly to the flat glass 1 from the viewpoint of applications of the cover glass with an outer frame 10 and effective use of space. The flat glass 1 and the outer frame 2 being perpendicular to each other means that an angle between the flat glass 1 and the outer surface of the outer frame 2 is perpendicular. Note that, “being perpendicular” does not necessarily have to be exactly 90 degrees, and it is sufficiently approximately perpendicular within a range of 90 degrees ±5 degrees.

A height of the outer frame 2 is preferably 350 μm to 4 mm, more preferably 400 μm to 3.5 mm, and still more preferably 500 μm to 3 mm. Here, the height of the outer frame 2 is preferably 350 μm or more, more preferably 400 μm or more, and still more preferably 500 Vm or more, from the viewpoint of preventing the cover glass from being damaged by the energy of light from the light source. On the other hand, the height of the outer frame 2 is preferably 4 mm or less, more preferably 3.5 mm or less, and still more preferably 3 mm or less, due to a demand for a small device height.

The outer frame 2 is preferably a sintered body of a laminated green sheet, since the height can be adjusted by changing the number of layers, and a higher frame can be formed as desired. The green sheet is to be described in detail later, and the green sheet is a sheet obtained by dispersing a glass ceramic precursor powder in, for example, a binder and then casting the dispersed powder.

### <<Glass Adhesive Layer>>

The glass adhesive layer 3 is a layer for bonding the flat glass 1 and the outer frame 2 to each other.

Unlike an adhesive layer made of an organic material such as a resin layer, the glass adhesive layer 3 is made of a glass and is therefore excellent in durability. In the case where a conductive film 5 made of an inorganic material to be described later is formed on the first main surface 1a of the flat glass 1, the flat glass 1 and the outer frame 2 are bonded to each other via the conductive film 5 in addition to the glass adhesive layer 3. In this case, the conductive film 5 is treated as a structure made of an inorganic material that is integrated with the flat glass 1, and the flat glass 1 and the outer frame 2 are bonded to each other via the glass adhesive layer 3.

The softening point Ts of the glass adhesive layer 3 is preferably lower than the softening point Ts of the borosilicate glass as the glass matrix of the glass ceramic of the outer frame 2 and lower than the glass transition point Tg of the flat glass 1. When the softening point Ts of the glass adhesive layer 3 is low as described above, the flat glass 1 and the outer frame 2 can be bonded to each other at a low temperature without causing damage and cracks to the flat glass 1.

The softening point Ts of the glass adhesive layer 3 varies depending on the softening point Ts of the borosilicate glass in the outer frame 2 or the glass transition point Tg of the flat glass 1, and is, for example, preferably 310° C. to 690° C., more preferably 320° C. to 680° C., and still more preferably 330° C. to 670° C. Here, the softening point Ts of the glass adhesive layer 3 is preferably 690° C. or lower, more preferably 680° C. or lower, and still more preferably 670° C. or lower, from the viewpoint of lowering the temperature during bonding. In addition, the softening point Ts of the glass adhesive layer 3 is preferably 310° C. or higher, more preferably 320° C. or higher, and still more preferably 330° C. or higher, from the viewpoint of remelting.

Note that, the softening point Ts of the glass adhesive layer is a temperature at the fourth inflection point in the DTA chart of the glass alone.

The glass adhesive layer 3 preferably contains a bismuth glass, a vanadium glass, or a borosilicate glass.

The bismuth glass is a glass containing bismuth oxide (Bi₂O₃), and the softening point Ts of the glass is lowered by containing bismuth oxide.

The bismuth glass may contain B₂O₃, CeO₂, SiO₂, RO, R′₂O, R″₂O₃, and R″O₂ in addition to B₂O₃.

The vanadium glass is a glass containing vanadium oxide (V₂O₅), and the softening point Ts of the glass is lowered by containing vanadium oxide.

The vanadium glass may contain TeO₂, B₂O₃, CeO₂, SiO₂, RO, R′₂O, R″₂O₃, and R′″O₂ in addition to V₂O₅.

The borosilicate glass is a borosilicate glass containing boron oxide (B₂O₃) and silicon dioxide (SiO₂), and the softening point Ts is lowered in the case where a content of silicon dioxide (SiO₂) is low.

The borosilicate glass may contain ZnO, RO, R′₂O, R″₂O₃, and R″′O₂ in addition to B₂O₃ and silicon dioxide (SiO₂).

By using the above glass for the glass adhesive layer, the flat glass 1 and the outer frame 2 can be bonded to each other simply by superimposing and heating the flat glass 1 and the outer frame 2, without the need to apply a voltage, unlike in anodic bonding. Therefore, the production process is also simplified.

A thickness of the glass adhesive layer 3 is preferably 10 μm to 30 μm, more preferably 11 μm to 25 μm, and still more preferably 12 μm to 20 μm. Here, the thickness of the glass adhesive layer 3 is preferably 10 μm or more, more preferably 11 μm or more, and still more preferably 12 μm or more, from the viewpoint of completely filling unevenness of a surface to be bonded to the flat glass 1 in the glass ceramic to be the outer frame 2, and obtaining favorable adhesion. When the glass adhesive layer 3 is too thick, the forming process is complicated. In addition, the thickness of the glass adhesive layer 3 is preferably 30 μm or less, more preferably 25 μm or less, and still more preferably 20 μm or less, from the viewpoint of preventing the occurrence of cracks due to expansion mismatch.

### <<Other Configurations>>

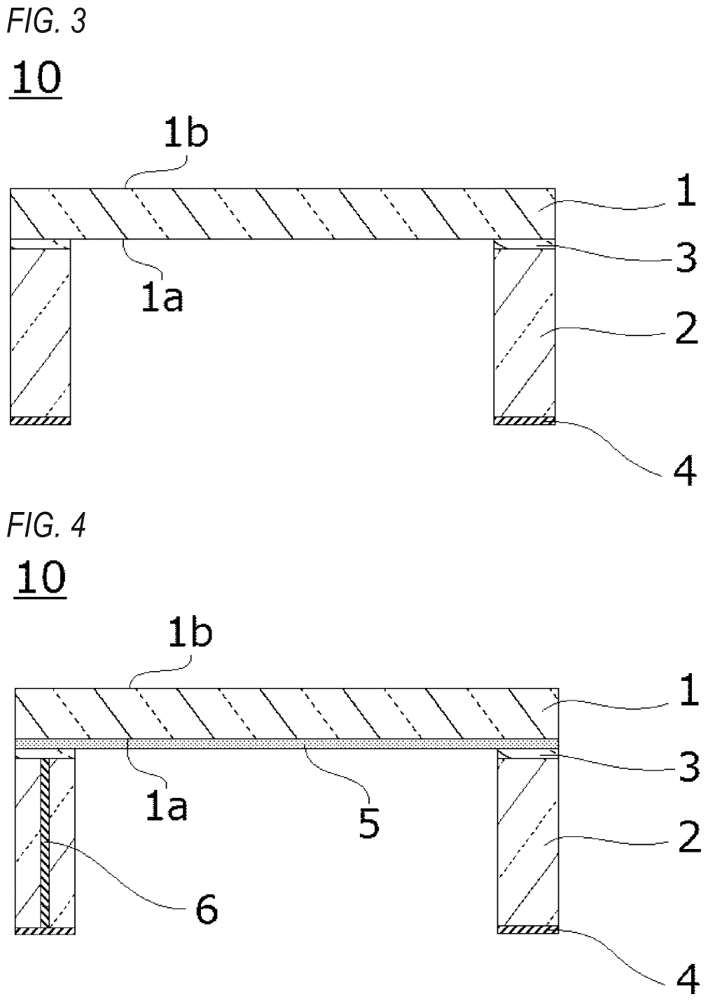

As shown in FIG. 3, the cover glass with an outer frame 10 according to the present embodiment preferably further includes a sealing material layer 4 on the surface of the outer frame 2 that is opposite to a surface facing the flat glass 1.

The sealing material layer 4 may be a layer made of a metal film or a layer made of a glass frit.

In the case where the sealing material layer 4 is made of a metal film, the substrate and the cover glass with an outer frame 10 can be hermetically sealed by sealing using a metal ring such as a gold-tin ring.

The metal film preferably has a layer (not shown) of a metal coating containing one or more selected from the group consisting of Au, Ag, Cu, and an Au—Sn alloy on the outermost surface thereof, and more preferably has an Ag layer or an Au layer on the outermost surface thereof, from the viewpoint of sealing properties using a metal ring. As a base for such a coating, a Ni coating, a Ti coating, or a coating of Pd, Pt, Cu, or the like (not shown) may be further provided.

Note that, in the case where the outer frame 2 includes a metal conductor 6 to be described later, the metal film preferably includes a metal coating using a metal same as that of the metal conductor 6.

In the case where the sealing material layer 4 is made of glass frit, the substrate and the cover glass with an outer frame 10 can be hermetically sealed by sealing with heating.

The glass frit is a sealing glass made of a low melting point glass, and any known glass may be used. For example, a low melting point glass such as a tin-phosphate glass, a bismuth glass, a vanadium glass, a lead glass, and a zinc borate alkaline glass is suitably used. Among them, in consideration of adhesiveness, adhesion reliability, reliability of hermetic sealability, and the influence on environment and human body, a low melting point glass such as a tin-phosphate glass, a bismuth glass, or a vanadium glass is more preferred. The glass frit may further contain an inorganic filler such as an electromagnetic wave absorber or a low thermal expansion filler.

In view of applications, the cover glass with an outer frame 10 according to the present embodiment preferably includes a system capable of detecting cracks in the flat glass 1. As an example of the system, as shown in FIG. 4, it is preferable to include the conductive film 5 on the first main surface 1a of the flat glass 1. It is also preferable that the metal conductor 6 be provided inside the outer frame 2 so as to penetrate the outer frame 2 and to be perpendicular to the flat glass 1, and that the conductive film 5 and the metal conductor 6 be electrically connected to each other.

The outer frame 2 is bonded to the first main surface 1a of the flat glass 1 via the glass adhesive layer 3. However, in the case where the conductive film 5 is formed on the entire region on the first main surface 1a of the flat glass 1, i.e., including a region to be bonded to the outer frame 2, as shown in FIG. 4, the flat glass 1 and the outer frame 2 are bonded to each other via the conductive film 5 in addition to the glass adhesive layer 3. In this case, the conductive film 5 made of an inorganic material is treated as a structure that is integrated with the flat glass 1, and the flat glass 1 and the outer frame 2 are bonded to each other via the glass adhesive layer 3.

Known inorganic materials can be used for the conductive film 5, and from the viewpoint of light permeability, a transparent conductive film is preferred, and examples thereof include an indium tin oxide (ITO) film, a SnO₂ film, or a ZnO film. Among them, an ITO film is preferred from the viewpoint of durability and resistance.

A thickness of the conductive film 5 is not particularly limited and is preferably 0.05 μm to 1 μm, more preferably 0.1 μm to 0.8 μm, and still more preferably 0.2 μm to 0.7 μm. Here, the thickness of the conductive film 5 is preferably 0.05 μm or more, more preferably 0.1 jam or more, and still more preferably 0.2 jam or more, from the viewpoint of ensuring stable electrical conductivity. In addition, the thickness of the conductive film 5 is preferably 1 μm or less, more preferably 0.8 jam or less, and still more preferably 0.7 jam or less, from the viewpoint of the transmissibility.

It is sufficient that the conductive film 5 is formed on at least a partial region on the first main surface 1a of the flat glass 1. However, in consideration of the purpose of detecting cracks in the flat glass 1, the conductive film 5 is preferably formed at least in an effective region, i.e., a region to be irradiated with light from a light source, and is more preferably formed in the entire region on the first main surface 1a of the flat glass 1.

In addition, in the case where a film or layer other than the conductive film 5 is formed on the first main surface 1a of the flat glass 1, the conductive film 5 is preferably formed outward than the other film or layer, that is, on the outermost surface on the side where the substrate equipped with a light emitting element or a light receiving element is located.

The metal conductor 6 is sometimes called a via, and refers to a conductor that electrically connects an upper layer wiring to a lower layer wiring. In the present embodiment, the metal conductor 6 is electrically connected to the conductive film 5 in order to connect the conductive film 5 to a detector for detecting cracks in the flat glass 1.

The metal conductor 6 can be a known one, and can be applied by using a known method. For example, before or after firing the glass ceramic constituting the outer frame 2, a hole penetrating the inside of the outer frame 2 is formed, and the metal conductor 6 is laid in the hole.

The metal conductor 6 may be any metal having electrical conductivity, and is preferably one or more metals selected from the group consisting ofAg, Au and Cu, and more preferably Ag, from the viewpoint of ease of production. The ease of production means that the metal conductor 6 can be sintered together with the glass ceramic to be the outer frame 2 during sintering and firing.

A shape of the metal conductor 6 is not particularly limited, and a metal wire is preferred from the viewpoint of easily passing through the inside of the outer frame 2. A via diameter, which is the diameter of the metal wire, is preferably 0.05 mm to 0.2 mm, and more preferably 0.05 mm to 0.1 mm. Here, the via diameter is more preferably 0.2 mm or less, and still more preferably 0.1 mm or less, from the viewpoint of preventing the unevenness of the metal conductor 6 from being too large and preventing cracks from occurring in the glass ceramic as the outer frame 2 during firing. In addition, the lower limit of the via diameter is not particularly limited, and the via diameter is preferably 0.05 mm or more from the viewpoint of preventing breakage of the metal conductor 6.

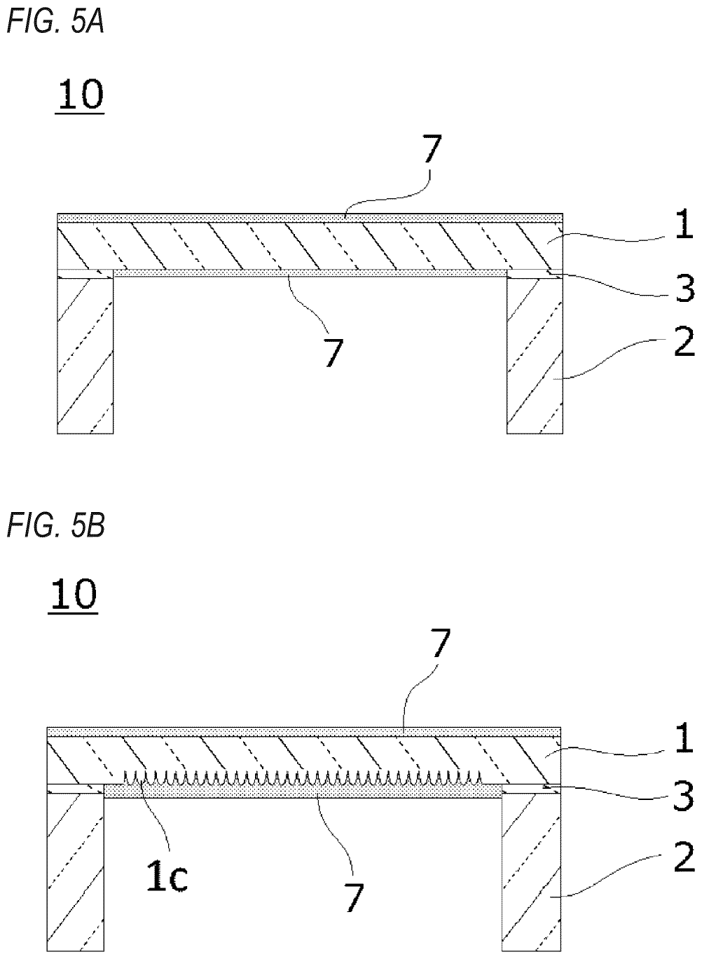

The cover glass with an outer frame 10 according to the present embodiment may further include an anti-reflective film 7 or the like on at least one main surface of the first main surface 1a or the second main surface 1b of the flat glass 1, as shown in FIG. 5A.

The anti-reflective film 7 is preferably formed on at least one of the main surfaces of the flat glass 1. That is, the anti-reflective film 7 may be formed on the first main surface 1a on the side where the substrate equipped with a light emitting element or a light receiving element is located, or may be formed on the other main surface, i.e., the second main surface 1b, and may be formed on both main surfaces, as shown in FIG. 5A.

In the case where the flat glass 1 includes the light diffusing portion 1c, the anti-reflective film 7 is preferably formed on a surface of the light diffusing portion 1c, i.e., outward than the light diffusing portion 1c, as shown in FIG. 5B.

The anti-reflective film 7 is not particularly limited as long as it has an anti-reflective function of reducing a reflectance of light at least at a design wavelength. The anti-reflective film 7 is preferably a film formed of an inorganic material from the viewpoint of preventing it from disappearing during firing of the outer frame 2, and examples thereof include a thin film having a single layer structure, or a multilayer film such as a dielectric multilayer film in which two or more dielectric layers having different refractive indices, such as SiO₂ and Ta₂O₅, are laminated.

The flat glass 1 may further include a layer, a film, or the like having certain functions in addition to those described above, so long as the effects of the present invention are not impaired.

Note that, in the case where the flat glass 1 includes a film formed of an inorganic material, such as the anti-reflective film 7 or the conductive film 5, and these films are formed up to a bonding region with the outer frame 2, the flat glass 1 and the outer frame 2 are bonded to each other via these films. In this case, these films are also considered to be integrated with the flat glass 1, and the flat glass 1 and the outer frame 2 are considered to be bonded to each other via the glass adhesive layer 3.

The cover glass with an outer frame 10 can be modified in any manner as long as the effects of the present invention are not impaired. For example, the metal conductor 6 can be removable by cutting a part of the outer frame 2 or by chamfering corners thereof so as to form a straight line passing through the flat glass 1 and the outer frame 2.

### <Semiconductor Light Emitting Device and Semiconductor Light Receiving Device>

A semiconductor light emitting device according to the present embodiment includes a cover glass with an outer frame, a substrate, and a light emitting element provided on the substrate.

As the cover glass with an outer frame, the one described in the above <Cover Glass with Outer Frame> can be used, and preferred embodiments are also the same. In particular, the cover glass with an outer frame preferably includes a sealing material layer made of a metal film or a glass frit, and more preferably includes a sealing material layer made of a metal film on the surface of the outer frame that is opposite to a surface facing the flat glass. The metal film preferably includes an Ag layer or an Au layer on the outermost surface thereof, and the cover glass with an outer frame is preferably integrated with the substrate via a gold-tin ring to hermetically seal the light emitting element.

A semiconductor light receiving device according to the present embodiment includes an cover glass with an outer frame, a substrate, and a light receiving element provided on the substrate.

As the cover glass with an outer frame, the one described in the above <Cover Glass with Outer Frame> can be used, and preferred embodiments are also the same. In particular, the cover glass with an outer frame preferably includes a sealing material layer made of a metal film or a glass frit, and more preferably includes a sealing material layer made of a metal film on the surface of the outer frame that is opposite to a surface facing the flat glass. The metal film preferably includes an Ag layer or an Au layer on the outermost surface thereof, and the cover glass with an outer frame is preferably integrated with the substrate via a gold-tin ring to hermetically seal the light receiving element.

In the semiconductor light emitting device or the semiconductor light receiving device, the cover glass with an outer frame 10 according to the present embodiment can have ensured perpendicularity and can also achieve adhesion with the cover glass even when the outer frame has a certain height or more. Further, damage and cracks on the surface of the flat glass are reduced, and the flat glass has high chemical resistance. For these reasons, the cover glass with an outer frame 10 according to the present embodiment is suitable for hermetically sealing a substrate in a semiconductor light emitting device or a substrate in a semiconductor light receiving device.

Examples of the light emitting element include a light emitting diode (LED) and a semiconductor laser (LD). In this case, the substrate is not particularly limited as long as it has an insulating property, and a ceramic substrate is preferred from the viewpoint of heat dissipation. The ceramic substrate is preferably, for example, an aluminum nitride (AlN) substrate, an alumina (Al₂O₃) substrate, or a low temperature co-fired ceramic (LTCC) substrate.

Examples of a semiconductor light emitting device equipped with these include a backlight for mobile phones and liquid crystal televisions, a light emitting part in operation buttons of small information terminals, illumination for automobiles or decorations, a deep ultraviolet LED for sterilization applications, a laser part of 3D distance measuring sensors, and other light sources.

Examples of the light receiving element include a MEMS sensor. In this case, the substrate is preferably a silicon substrate.

<Method for Producing Cover Glass with Outer Frame>

A method for producing the cover glass with an outer frame 10 according to one embodiment is described.

A method for producing the glass ceramic to be the outer frame 2 of the cover glass with an outer frame 10 is not particularly limited, and for example, the glass ceramic is obtained by sintering with forming and firing a glass ceramic precursor, which is a mixture of a filler and a borosilicate glass powder as a glass matrix, and firing the formed product. Specific examples thereof include a method in which the above precursor is formed into a sheet called a green sheet and fired.

An example of a method for producing a green sheet is shown below.

First, raw materials are blended and mixed to obtain a desired glass composition, and the raw material mixture is melted, cooled, and pulverized to obtain a glass powder. The glass powder obtained by pulverization is fired to form a glass matrix, which determines the glass composition of the glass ceramic. Therefore, the borosilicate glass powder in the present embodiment contains boron oxide and silicon dioxide, and further contains aluminum oxide. Preferred embodiments of the glass powder is the same as the preferred embodiments described for the glass matrix in the above <Cover Glass with Outer Frame>.

A melting temperature for the raw material mixture is preferably, for example, 500° C. to 800° C. or higher, and a melting time is preferably, for example, 30 minutes to 60 minutes.

The pulverization may be a dry pulverization method or a wet pulverization method. In the case of the wet pulverization method, water, ethanol, or the like can be used as a solvent.

For the pulverization, for example, a pulverizer such as a roll mill, a ball mill, or a jet mill can be used.

A 50% particle diameter (D₅₀), which indicates the size of the glass powder, is preferably 0.5 μm to 10 μm, and more preferably 1 μm to 9 μm. Here, the 50% particle diameter (D₅₀) is preferably 0.5 μm or more, and more preferably 1 μm or more, from the viewpoint of preventing the glass powder from agglomerating and being difficult to handle, and preventing the time required for powderization from increasing. In addition, the 50% particle diameter (D₅₀) is preferably 10 μm or less, and more preferably 9 μm or less, from the viewpoint of preventing an increase in glass softening point Ts and preventing insufficient sintering.

A maximum particle diameter of the glass powder is preferably 20 Lm or less, and more preferably 10 μm or less, from the viewpoint of obtaining favorable sinterability and the viewpoint of preventing a decrease in reflectance due to the presence of undissolved components remaining in the sintered body.

The particle diameter can be adjusted by, for example, classifying the powder after pulverization as necessary.

Next, the glass powder and a filler are mixed to obtain a glass ceramic precursor.

The filler may contain aluminum oxide, and may be the same as those described in the above <Cover Glass with Outer Frame>, and preferred embodiments are also the same.

The filler is mixed to have a total volume fraction of 40% to 65% in the obtained glass ceramic. In addition, the filler is mixed such that a volume fraction of aluminum oxide is 10% to 65% in the glass ceramic.

The glass ceramic precursor is blend with an organic solvent, a plasticizer, a binder, a dispersant, or the like, as required, to prepare a slurry or paste.

Examples of the organic solvent include an alcohol, a ketone, and an aromatic hydrocarbon. More specifically, toluene, methyl ethyl ketone, methanol, 2-butanol, xylene, or the like can be used, and these may be used alone or in combination of two or more kinds thereof.

Examples of the plasticizer include adipic acid-based and phthalic acid-based plasticizers. More specifically, bis(2-ethylhexyl) adipate, dibutyl phthalate, dioctyl phthalate, butyl benzyl phthalate, or the like can be used.

Examples of the binder include a thermally decomposable resin. More specifically, an acrylic resin, polyvinyl butyral, or the like can be used.

Examples of the dispersant include a surfactant-type dispersant. More specifically, DISPERBYK180 (product name, manufactured by BYK-Chemie GmbH) or the like can be used.

The obtained slurry or paste is cast into a sheet, which is called a green sheet. More specifically, for example, a slurry or paste is applied onto a film and then dried to obtain a green sheet.

A thickness of the green sheet is not particularly limited, and can be adjusted by adjusting the thickness during coating, a slurry concentration, or the like.

Next, a method for forming the outer frame 2 from the green sheet obtained above and a method for bonding the outer frame 2 to the flat glass 1 are described.

First, an appropriate number of green sheets are laminated depending on the desired height of the outer frame 2. Thereafter, the interior is punched out with a punching machine to form an outer frame shape. At this time, in the case where the cover glass with an outer frame 10 includes the metal conductor 6, a through hole for the metal conductor 6 to penetrate may also be formed. Note that, in forming the glass ceramic, one formed by forming the glass ceramic precursor using a mold or the like may be used instead of the green sheet. However, the green sheet is preferred since it is easier to pass the wiring through each layer.

The green sheets may be prepared one by one to fit the desired outer frame shape, or a large green sheet may be prepared and punched out in a plurality of places with a punching machine to form an outer frame that is a multi-piece connected substrate in which a plurality of pieces are connected.

A laminate of green sheets is fired separately to form a glass ceramic in advance, and then bonded to a flat glass via a glass adhesive layer.

Among them, it is preferable that the green sheets be laminated and punched out to form a multi-piece connected substrate in which a plurality of pieces are connected and then fired to form a multi-piece outer frame, to which the flat glass is bonded via the glass adhesive layer.

The laminate of green sheets is degreased and then fired to form a glass ceramic in which a filler is dispersed in a glass matrix, thereby obtaining the outer frame 2.

The green sheet may be degreased as necessary, and is preferably degreased at a temperature of, for example, 350° C. to 550° C. A degreasing time is preferably, for example, 1 hour to 10 hours.

A firing temperature for the green sheet is equal to or higher than the glass softening point Ts of the glass matrix in the glass ceramic.

The specific firing temperature varies depending on the glass composition of the glass ceramic, and is preferably 750° C. to 1000° C., more preferably 775° C. to 950° C. and still more preferably 800° C. to 900° C. Here, the firing temperature is preferably 750° C. or higher, more preferably 775° C. or higher, and still more preferably 800° C. or higher, from the viewpoint of obtaining sufficient sinterability. In addition, the firing temperature is preferably 1000° C. or lower, more preferably 950° C. or lower, and still more preferably 900° C. or lower, from the viewpoint of preventing melting of a metal constituting the sealing material layer 4 or a metal constituting the metal conductor 6.

A firing time for the green sheet is preferably 10 minutes to 120 minutes, more preferably 15 minutes to 90 minutes, and still more preferably 25 minutes to 60 minutes. Here, the firing time is preferably 10 minutes or longer, more preferably 15 minutes or longer, and still more preferably 25 minutes or longer, from the viewpoint of obtaining sufficient sinterability. In addition, the firing time is preferably 120 minutes or shorter, more preferably 90 minutes or shorter, and still more preferably 60 minutes or shorter, from the viewpoint of productivity.

A shape of the outer frame 2 is determined by a shape of the green sheet. That is, an inner shape of the outer frame 2 is derived from the shape formed when the green sheet is punched out. In addition, an outer shape of the outer frame 2 is derived from an outer shape of the green sheet. In the case of obtaining the cover glass with an outer frame 10 by dividing a multi-piece connected substrate, the shape of the multi-piece connected substrate in dividing after firing is the outer shape of the outer frame 2.

The flat glass 1 can be produced by using a known method, or a commercially available product may be used.

For example, in order to obtain a glass having a desired composition, glass raw materials are blended, and then heated and melted. Thereafter, the molten glass is homogenized by bubbling, stirring, addition of a refining agent, or the like, and formed into a glass plate having a predetermined thickness by using a known forming method, followed by annealing. After the molten glass is homogenized, the homogenized glass may be formed into a block shape, followed by annealing, and cut into a flat plate shape.

Examples of a method for forming a flat glass include a float method, a press method, a fusion method, and a down-draw method. In particular, a down-draw method is preferred from the viewpoint of controlling the glass thickness.

In the case of forming the conductive film 5 on the main surface of the flat glass 1 to be electrically connected to the metal conductor 6, it is preferable to form the conductive film 5 before superimposing the outer frame 2 and the flat glass 1 via the glass adhesive layer 3.

The conductive film 5 can be formed on the first main surface 1a of the flat glass 1 by using a known method. For example, in the case where the conductive film is an ITO film, it is preferably formed by using a sputtering method.

In addition, in the case where the light diffusing portion 1c or the anti-reflective film 7 is provided on the same first main surface 1a of the flat glass 1, the conductive film 5 is preferably formed on the outermost surface thereof, i.e., on a side closest to the substrate.

In the case where the light diffusing portion 1c is directly processed or the anti-reflective film 7 is formed on the main surface of the flat glass 1, such processing or film formation may be performed before superimposing the outer frame 2 and the flat glass 1 via the glass adhesive layer 3, or may be performed after the cover glass with an outer frame 10 is obtained. However, in the case where the light diffusing portion 1c or the conductive film 5 is provided as described above, it is preferable to process the light diffusing portion 1c or to form the conductive film 5 before superimposing the outer frame 2 and the flat glass 1 via the glass adhesive layer 3.

The anti-reflective film 7 can be formed by using a known method. For example, a high refractive index layer and a low refractive index layer can be laminated in this order on the main surface of the flat glass 1 by using a known film formation method such as a sputtering method or a vapor deposition method.

Note that, in the case where the anti-reflective film 7 is formed on the main surface of the flat glass 1 that is opposite to a the side to be bonded to the outer frame 2, i.e., on the second main surface 1b, it may be formed after the cover glass with an outer frame 10 is obtained.

The softening point Ts of the glass adhesive layer 3 is preferably lower than the softening point Ts of the borosilicate glass and lower than the glass transition point Tg of the flat glass. Accordingly, the flat glass 1 and the outer frame 2 can be bonded to each other at a low temperature without causing damage and cracks thereto.

A bonding temperature is, for example, preferably 330° C. to 700° C., and more preferably 350° C. to 690° C. A bonding time is preferably, for example, 10 minutes to 60 minutes.

Examples of a glass having a softening point Ts lower than the softening point Ts of the borosilicate glass and lower than the glass transition point Tg of the flat glass include a bismuth glass, a vanadium glass, and a borosilicate glass.

In order to set the thickness of the glass adhesive layer 3 to be 10 μm or more, a method of using a screen plate having a large mesh size, a method of performing printing a plurality of times, or the like can be used.

In addition, the glass adhesive layer 3 may be thickened by printing a glass frit to be the glass adhesive layer 3 on both the first main surface 1a of the flat glass 1 and the surface of the outer frame 2.

The thickness of the glass adhesive layer 3 is preferably 30 μm or less from the viewpoint of preventing the process from being complicated and preventing cracks due to expansion mismatch.

In the case where the cover glass with an outer frame is a multi-piece connected substrate, a single cover glass with an outer frame 10 can be obtained by performing cutting between adjacent holes with a dicing saw or laser.

Before performing firing to bond the outer frame to the flat glass via the glass adhesive layer, it is preferable, from the viewpoint of adhesion, to smooth both surfaces of the glass ceramic, that is, both the surface in contact with the glass adhesive layer and the surface on the opposite side, by polishing or the like.

Specifically, it is preferable to smooth a maximum height roughness Rz of the surface that is opposite to the surface in contact with the glass adhesive layer, since this improves the sealability by the sealing material layer. The maximum height roughness Rz is preferably 5 μm or less, more preferably 4.5 μm or less, and still more preferably 4 μm or less. The maximum height roughness Rz of the glass ceramic obtained by firing a glass ceramic precursor is generally about 10 μm, but the maximum height roughness Rz can be reduced to 5 μm or less by performing a flattening step such as polishing.

The sealing material layer 4 is formed after a flattening step such as polishing is performed on both surfaces of the outer frame 2 that has been fired to be a glass ceramic.

The sealing material layer 4 is formed of a metal film or a glass frit, and can be formed by using a known method. For example, in the case where the sealing material layer 4 is made of a metal film, it can be formed by applying a conductive paste in a paste form prepared by adding a vehicle such as ethyl cellulose, and if necessary, a solvent, or the like, to a metal powder by using a screen printing method. In addition, in the case where the sealing material layer 4 is made of a glass frit, it can be formed by applying a paste in which a glass frit made of a low melting point glass is mixed with a vehicle obtained by dissolving a resin, which is a binder component, in a solvent.

In the case of forming a coating as a base on the surface of the metal film of the sealing material layer 4 or between the outer frame and the metal film, the coating can be formed by using a known method. For example, it may be formed by electrolytic plating, electroless plating, a sputtering method, or a vapor deposition method.

The metal conductor 6 can be formed by filling through holes formed in advance with, for example, a metal paste by using a screen printing method. The metal conductor 6 may be formed by filling through holes of the green sheet that has been formed into an outer frame shape with a metal paste, or filling through holes of the outer frame that has been fired to be a glass ceramic with a metal paste.

The cover glass with an outer frame according to the present embodiment have been described in detail above, and other embodiments of the present embodiment are as follows.

[1]A cover glass with an outer frame including:
a flat glass having a first main surface and a second main surface facing that are opposite sides; and
an outer frame bonded to the first main surface of the flat glass via a glass adhesive layer, in which
the outer frame is made of a glass ceramic in which a filler is dispersed in a borosilicate glass,
the borosilicate glass and the filler both contain aluminum oxide,
the filler has a volume fraction of 40% to 65% in the glass ceramic,
the aluminum oxide contained in the filler has a volume fraction of 10% to 65% in the glass ceramic, and
an absolute value of a difference in average thermal expansion coefficient at 50° C. to 350° C. between the flat glass and the outer frame is 20×10⁻⁷/° C. or less.

[2] The cover glass with an outer frame according to the above [1], in which a surface of the outer frame that is opposite to a surface facing the flat glass has a maximum height roughness Rz of 5 μm or less.

[3] The cover glass with an outer frame according to the above [1] or [2], in which
the glass adhesive layer has a softening point Ts lower than a softening point Ts of the borosilicate glass, and
the softening point Ts of the glass adhesive layer is lower than a glass transition point Tg of the flat glass.

[4] The cover glass with an outer frame according to the above [3], in which
the glass adhesive layer includes a bismuth glass, a vanadium glass, or a borosilicate glass, and
the glass adhesive layer has a thickness of 10 μm to 30 μm.

[5] The cover glass with an outer frame according to any one of the above [1] to [4], in which the outer frame has a height of 350 μm to 4 mm.

[6] The cover glass with an outer frame according to any one of the above [1] to [5], in which
the flat glass includes a light diffusing portion on the first main surface, and
the light diffusing portion is formed by directly processing the flat glass.

[7] The cover glass with an outer frame according to the above [6], in which the light diffusing portion is formed inside a region of the flat glass where the outer frame is bonded.

[8] The cover glass with an outer frame according to any one of the above [1] to [7], in which
the flat glass includes a conductive film on the first main surface,
a metal conductor is provided inside the outer frame, the metal conductor penetrating the outer frame and being provided perpendicular to the flat glass, and
the conductive film and the metal conductor are electrically connected to each other.

[9] The cover glass with an outer frame according to any one of the above [1] to [8], further including:
a sealing material layer on the surface of the outer frame that is opposite to a surface facing the flat glass, in which
the sealing material layer is made of a metal film or a glass frit.

[10] The cover glass with an outer frame according to the above [9], in which
the sealing material layer is made of a metal film, and
the metal film includes an Ag layer or an Au layer on an outermost surface of the metal film.

[11]A semiconductor light emitting device including:
the cover glass with an outer frame according to the above [10];
a substrate; and;
a light emitting element provided on the substrate, in which
the cover glass with an outer frame is integrated with the substrate via the sealing material layer in the cover glass with an outer frame and a gold-tin ring, to hermetically seal the light emitting element.

[12]A semiconductor light receiving device including:
the cover glass with an outer frame according to the above [10];
a substrate; and;
a light receiving element provided on the substrate, in which
the cover glass with an outer frame is integrated with the substrate via the sealing material layer in the cover glass with an outer frame and a gold-tin ring, to hermetically seal the light receiving element.

### EXAMPLES

Hereinafter, the present invention is described in detail with reference to Examples, but the present invention is not limited thereto.

Example 1-2, Example 1-4, and Example 1-6 are Inventive Examples, and Example 1-1, Example 1-3, Example 1-5, and Example 1-7 to Example 1-10 are Comparative Examples. Example 2-2 to Example 2-4 are Inventive Examples, and Example 2-1 is Comparative Example. Example 3-1, Example 3-2, and Example 3-5 are Inventive Examples, and Example 3-3 and Example 3-4 are Comparative Examples. Example 4-1 is Inventive Example, and Example 4-2 is Reference Example.

Note that, Example 1-1 to Example 1-10 and Example 2-1 to Example 2-4 are only a glass ceramic to be an outer frame, and are not an cover glass with an outer frame in which an outer frame made of a glass ceramic is bonded to a flat glass, but a shape retention property, sinterability, and chemical resistance of the outer frame can be considered to be the same as in the case of an cover glass with an outer frame, so that these are treated as Inventive Examples or Comparative Examples.

In addition, Example 4-1 and Example 4-2 do not include a light emitting element or a light receiving element, but the sealability between the substrate and the cover glass with an outer frame can be considered to be the same as that of a semiconductor light emitting and receiving device including a light emitting element or a light receiving element, so that these are treated as Inventive Examples or Comparative Examples.

### Outer Frame: Example 1-1 to Example 1-10

A borosilicate glass containing 10 wt % of aluminum oxide (product name ASF-1860 manufactured by AGC Inc.) was mixed with a filler shown in Table 1 so that the filler had a volume fraction shown in Table 1, to obtain a glass ceramic precursor. Note that, cordierite is a ceramic made of three components, i.e., 2MgO·2Al₂O₃·5SiO₂, and contains aluminum oxide. In addition, forsterite is a ceramic made of two components, i.e., 2MgO·SiO₂, and does not contain aluminum oxide.

The glass ceramic precursor obtained above was pressure-formed into a cylindrical green compact having a diameter of 17 mm and a height of 5 mm, followed by firing at 850° C., to obtain a glass ceramic.

In Table 1, the “filler volume fraction” refers to the volume fraction of the filler in the glass ceramic, and the “alumina volume fraction” refers to the volume fraction of aluminum oxide contained in the filler in the glass ceramic.

TABLE 1

| | | | | Filler | Alumina | Shape | |
|---|---|---|---|---|---|---|---|
| | | | Firing | volume | volume | retention | |
| | Glass matrix | Filler | temperature | fraction | fraction | property | Sinterability |
| Example 1-1 | Borosilicate | Cordierite | 850° C. | 38% | 10% | B | A |
| Example 1-2 | glass (containing | Cordierite | | 51% | 12% | A | A |
| Example 1-3 | aluminum oxide) | Cordierite | | 68% | 16% | A | B |
| Example 1-4 | | Alumina | | 47% | 47% | A | A |
| Example 1-5 | | Alumina | | 70% | 70% | A | B |
| Example 1-6 | | Alumina + | | 45% | 32% | A | A |
| | | zirconia | | | | | |
| Example 1-7 | | Alumina + | | 48% | 4% | A | B |
| | | zirconium | | | | | |
| | | phosphate | | | | | |
| Example 1-8 | | Alumina + | | 53% | 7% | A | B |
| | | zirconium | | | | | |
| | | phosphate | | | | | |
| Example 1-9 | | Zirconium | | 43% | 0% | A | B |
| | | phosphate | | | | | |
| Example 1-10 | | Forsterite | | 43% | 0% | A | B |

The obtained glass ceramics were evaluated for the shape retention property and the sinterability.

Specifically, the shape retention property was evaluated using a stereo microscope MVX10 manufactured by EVIDENT.

The results are shown as the “shape retention property” in Table 1, with “A” indicating that the glass ceramic has high perpendicularity and an excellent shape retention property. Specifically, since the glass ceramic is produced by firing a cylindiical green compact, the glass ceramic also has a cylindrical shape similar to that of the green compact. However, it is difficult to obtain a perfect similar shape due to firing. Therefore, the case where a difference represented by (I1-L2) was 1.0 mm or less was considered to be favorable and was evaluated as “A”, L1 being the longest length in a lateral direction of a cross section of the cylindrical glass ceramic, that is, a direction corresponding to the diameter 2r of a circle as a top surface or bottom surface of the cylinder, and L2 being the diameter of a circle in the lateral direction of a region where the glass ceramic and the flat glass were bonded to each other, i.e., the bottom surface of the cylinder.

In addition, in Table 1, the “shape retention property” is evaluated as “B” in the case where the difference represented by (L1-L2) above was more than 1.0 mm, indicating that the perpendicularity of the glass ceramic is lost and the glass ceramic is rounded in the lateral direction, resulting in a poor result.

The sinterability was evaluated using a stereo microscope MVX10 manufactured by EVIDENT.

The results are shown as the “sinterability” in Table 1, with “A” indicating that no pores of 1 mm or more are observed when the surface of the glass ceramic is observed with a microscope, which is favorable, and “B” indicating that pores of 1 mm or more are observed and that the sinterability of the glass component and the filler in the glass ceramic is insufficient and poor.

As seen from the above results, when the volume fraction of the filler in the glass ceramic is 40% to 65% and the volume fraction of aluminum oxide contained in the filler in the glass ceramic is 10% to 65%, it is possible to achieve both the shape retention property and the sinterability, which are previously difficult to achieve at the same time. Since the shape retention property is favorable, the perpendicularity of the outer frame is achieved. In addition, since the wettability between the filler and the borosilicate glass is improved and the sinterability of the glass ceramic is improved, a highly hermetic outer frame can be obtained.

### Outer Frame: Example 2-1

A bismuth glass (ASF-4001B manufactured by AGC Inc.) was mixed with a filler shown in Table 2 so that the filler has a volume fraction shown in Table 2, to obtain a glass ceramic precursor powder.

A mixture, obtained by mixing the glass ceramic precursor with toluene, methyl ethyl ketone, methanol, and 2-butanol in a mass ratio of 3:3:1:1 as an organic solvent, was blended and mixed with bis(2-ethylhexyl) adipate as a plasticizer, an acrylic resin as a binder, and a dispersant (product name DISPERBYK180 manufactured by BYK-Chemie GlbH) to prepare a slurry.

The slurry was applied onto a polyethylene terephthalate (PET) film by using a doctor blade method and dried to produce a green sheet having a thickness of 200 μm.

Six green sheets obtained above were laminated, cut into a 45-mm square sheet laminate, and fired at the firing temperature shown in Table 2.

In Table 2, the “filler volume fraction” refers to the volume fraction of the filler in the glass ceramic, and the “alumina volume fraction” refers to the volume fraction of aluminum oxide contained in the filler in the glass ceramic.

### Outer Frame: Example 2-2 to Example 2-4

A borosilicate glass containing 10 wt % of aluminum oxide (product name ASF-1860 manufactured by AGC Inc.) was mixed with a filler shown in Table 2 so that the filler had a volume fraction shown in Table 2, to obtain a glass ceramic precursor powder.

A mixture, obtained by mixing the glass ceramic precursor with toluene, methyl ethyl ketone, methanol, and 2-butanol in a mass ratio of 4:4:1:1 as an organic solvent, was blended and mixed with bis(2-ethylhexyl) adipate as a plasticizer, a butyral resin as a binder, and a dispersant (product name DISPERBYK180 manufactured by BYK-Chemie GmbH) to prepare a slurry.

The slurry was applied onto a polyethylene terephthalate (PET) film by using a doctor blade method and dried to produce a green sheet having a thickness of 200 μm.

Six green sheets obtained above were laminated, cut into a 45-mm square sheet laminate, and fired at the firing temperature shown in Table 2.

TABLE 2

| | | | | Filler | Alumina | Chemical resistance | |
|---|---|---|---|---|---|---|---|
| | | | Firing | volume | volume | | Weight loss rate |
| | Glass matrix | Filler | temperature | fraction | fraction | Erosion | N₃ AVE. |
| Example 2-1 | Bismuth glass | Cordierite | 520° C. | 44% | 10% | Yes | 5.90% |
| Example 2-2 | Borosilicate glass | Cordierite | 850° C. | 51% | 12% | No | 0.00% |
| | (containing aluminum | | | | | | |
| | oxide) | | | | | | |
| Example 2-3 | Borosilicate glass | Alumina | 850° C. | 47% | 47% | No | 0.00% |
| | (containing aluminum | | | | | | |
| | oxide) | | | | | | |
| Example 2-4 | Borosilicate glass | Alumina + | 850° C. | 45% | 32% | No | 0.00% |
| | (containing aluminum | zirconia | | | | | |
| | oxide) | | | | | | |

The obtained glass ceramics were evaluated for the chemical resistance.

Specifically, in an acid resistance test, the glass ceramic was immersed in a 10% aqueous sulfuric acid solution at 25° C. for 2 hours. The presence or absence of erosion after immersion was visually checked, and a weight loss rate was calculated based on a change in weight before and after immersion in the 10% aqueous sulfuric acid solution.

The results are shown as the “chemical resistance” in Table 2.

As seen from the above results, in Example 2-2 to Example 2-4 in which a borosilicate glass was used as the glass matrix, no erosion or weight loss due to the 10% aqueous sulfuric acid solution was observed, so that the chemical resistance is more excellent than a known glass ceramic in which a bismuth glass was used as the glass matrix. Therefore, it suggests that the glass ceramics have high chemical resistance in metallization or in mounting on a semiconductor light emitting device, a semiconductor light receiving device, or the like.

### Cover Glass with Outer Frame: Example 3-1 to Example 3-5

A borosilicate glass containing 10 wt % of aluminum oxide (product name ASF-1860 manufactured by AGC Inc.) was mixed with cordierite as a filler such that the volume fraction of the filler in the glass ceramic was 51% and the volume fraction of aluminum oxide contained in the filler in the glass ceramic was 12%, to obtain a glass ceramic precursor powder.

A mixture, obtained by mixing the glass ceramic precursor with toluene, methyl ethyl ketone, methanol, and 2-butanol in a mass ratio of 4:4:1:1 as an organic solvent, was blended and mixed with bis(2-ethylhexyl) adipate as a plasticizer, a butyral resin as a binder, and a dispersant (product name DISPERBYK180 manufactured by BYK-Chemie GmbH) to prepare a slurry.

The slurry was applied onto a polyethylene terephthalate (PET) film by using a doctor blade method and dried to produce a green sheet.

Six green sheets obtained above were laminated, and a punching machine was used to punch out 8×8 square holes of 4.0 mm×4.0 mm to obtain an unsintered panel having a multi-piece outer frame shape in which 64 pieces were connected.

The above panel was fired at 850° C. to obtain a multi-piece outer frame made of a glass ceramic having a thickness of about 1 mm and having 8×8 square holes of 3.4 mm×3.4 mm.

Next, both the main surface of the outer frame facing the flat glass and the main surface opposite thereto were polished to have a maximum height roughness Rz of 3 μm.

As a glass frit paste, a vanadium glass (TNS062-ZC2-P150 manufactured by AGC Inc.) was used in Example 3-1 and Example 3-5, and a bismuth glass (AP4115AB manufactured by AGC Inc.) was used in Example 3-2, Example 3-3, and Example 3-4, each of which was used for printing using a screen printer to form a frame shape around one opening of the glass ceramic. For the screen printing, a screen plate having a mesh size of 325 and an emulsion thickness of 10 mr xwas used. The paste was then dried at 120° C. for 10 minutes, and then pre-fired at the firing temperature shown in Table 3 for 10 minutes.

On the other hand, as the flat glass, a glass plate made of an alkali-free borosilicate glass, having a size of 50 mm×50 mm and a thickness of 0.5 mm (EN-A1 manufactured by AGC Inc.), a glass plate made of a borosilicate having a size of 50 mm×50 mm and a thickness of 0.5 mm (D263 (registered trademark) manufactured by Schott), and a glass plate made of aborosilicate having a size of 50 mm×50 mm and a thickness of 0.7 mm (TEMPAX (registered trademark) manufactured by Schott) were prepared. The average thermal expansion coefficients of these flat glasses are shown as “CTE” in Table 3.

The glass frit paste shown in Table 3 was used for printing on these flat glasses in the same pattern as above, and was similarly pre-fired at the firing temperature shown in Table 3 for 10 minutes.

Next, the above flat glass and glass ceramic were provided such that the glass frit printing surfaces face each other, and while the four corners were fixed with clips, they were fired for 1 hour at the firing temperature shown in Table 3, thereby bonding the flat glass and the glass ceramic via the glass adhesive layer. Accordingly, an cover glass with an outer frame as a multi-piece connected substrate was obtained.

The thickness of the glass adhesive layer after bonding is as shown in Table 3.

TABLE 3

| | Outer frame | | | Flat glass | | |
|---|---|---|---|---|---|---|
| | | | CTE | Glass | CTE | |
| | Glass matrix | Filler | (×10⁻⁷/° C.) | material | (×10⁻⁷/° C.) | \|ΔCTE\| |
| Example 3-1 | Borosilicate glass | Cordierite | 39 | EN-A1 | 39 | 0 |
| Example 3-2 | (containing | filler volume | | EN-A1 | 39 | 0 |
| Example 3-3 | aluminum oxide) | fraction: 51% | | D263 | 77 | 38 |
| Example 3-4 | (softening point: | alumina volume | | D263 | 77 | 38 |
| Example 3-5 | 830° C.) | fraction: 12% | | TEMPAX | 33 | 6 |

| | Glass adhesive layer | | | | |
|---|---|---|---|---|---|
| | | Firing | Softening | | |
| | | temperature | point | Thickness | |
| | Glass frit | (° C.) | (° C.) | (μm) | Bonding |
| Example 3-1 | Vanadium | 380 | 340 | 16 | A |
| | glass | | | | |
| Example 3-2 | Bismuth | 440 | 402 | 15 | A |
| | glass | | | | |
| Example 3-3 | Bismuth | 440 | 402 | 13 | A |
| | glass | | | | cracks |
| Example 3-4 | Bismuth | 440 | 402 | 8 | B |
| | glass | | | | |
| Example 3-5 | Vanadium | 380 | 340 | 15 | A |
| | glass | | | | |

The obtained cover glasses with outer frame as multi-piece connected substrates were evaluated for bondability between the flat glass and the outer frame.

Specifically, the cover glass with an outer frame was placed with the opening facing upward, and a fluorescent ink was dripped thereto, to check the presence or absence of the ink penetrating a bonded portion between the flat glass and the outer frame by observation using a microscope.

The results are shown as the “bonding” in Table 3, with the case of no penetration of the fluorescent ink evaluated as favorable and indicated by “A”, and the case of penetration of the fluorescent ink evaluated as poor and indicated by “B”.

In Table 3, the absolute value of the difference in average thermal expansion coefficient between the flat glass and the outer frame is represented by |ΔCTE|. In all of Example 3-1, Example 3-2, and Example 3-5 in which |ACTE| is 20×10⁻⁷/° C. or less, favorable bondability is observed. In addition, in comparison with Example 3-4, in Example 3-3, the bonding is achieved by increasing the thickness of the glass adhesive layer to a certain extent, but cracks in the flat glass are observed, and it is not a suitable cover glass with an outer frame. In the cover glasses with outer frame in Example 3-1, Example 3-2, and Example 3-5, even when the thickness of the glass adhesive layer was 10 μm or more, the flat glass did not crack and the bondability is favorable.

### Device: Example 4-1

For the cover glass with an outer frame as a multi-piece connected substrate obtained in Example 3-1 above, a masking process was performed on the openings, and metal layers of Ti 0.1 μm/Pt 0.2 μm/Au 0.1 μm were formed in this order by vapor deposition on the surface of the Ag layer as a sealing material layer. That is, the outermost surface of the sealing material layer is the Au layer. Subsequently, the 8×8 square openings were diced along a center line by blade dicing to obtain an individual cover glass with an outer frame with a sealing material layer.

On the other hand, a 50-mm square AlN substrate was used as a substrate for a semiconductor light emitting and receiving device, and metal layers of Ti 0.1 μm/Pt 0.2 μm/Au 0.1 μm were formed in this order by vapor deposition on one of the main surfaces. That is, the outermost surface of the metal layer is the Au layer. Subsequently, the substrate was diced into individual pieces of 5.0 mm square by blade dicing.

Thereafter, the cover glass with an outer frame obtained above, a gold-tin ring, and the AlN substrate obtained above were provided in this order, followed by heating at 300° C. for 1 minute under a N₂ atmosphere in a manner that the AlN substrate was in contact with a hot plate, to prepare a sealed sample.

Note that, when they were provided, alignment was performed using a microscope such that an opening of the gold-tin ring was aligned with the opening of the cover glass with an outer frame. The gold-tin ring had an outer diameter of 5 mm, an inner diameter of 3.4 mm, and a thickness of 20 μm.

### Device: Example 4-2

The cover glass with an outer frame obtained in Example 3-1 above was similarly diced to obtain an cover glass with an outer frame with a sealing material layer, except that polishing to have a maximum height roughness Rz of 3 μm was not performed on both the main surface of the glass ceramic facing the flat glass plate and the main surface opposite thereto. The maximum height roughness Rz of both the main surfaces was 10 μm.

Using this cover glass with an outer frame, a sealed sample was prepared in the same manner as in Example 4-1.

The sealed samples in Example 4-1 and Example 4-2 were subjected to a gross leak test.

In the gross leak test, a pressure of He was applied at 5 kN for 2 hours, then the sealed sample was immersed in Fluorinert at 125° C. for 30 seconds, and the occurrence of He bubbles was visually checked.

No gross leak was observed in Example 4-1, and a gross leak was observed in Example 4-2. As seen from the above results, in the case of mounting the cover glass with an outer frame according to the present embodiment on a light emitting and receiving device or the like, it is preferable to perform polishing or the like on at least the surface of the outer frame to be in contact with the sealing material layer before forming the sealing material layer, so that the maximum height roughness Rz is 5 μm or less.

When the maximum height roughness Rz is more than 5 μm, it is difficult to fill the unevenness on the main surface of the outer frame with the thickness of the sealing material layer, and as a result, it is thought that the hermetic sealability is decreased.

Although the present invention has been described in detail with reference to specific embodiments, it is apparent to those skilled in the art that various changes and modifications can be made without departing from the spirit and scope of the present invention. The present application is based on a Japanese Patent Application (No. 2022-122179) filed on Jul. 29, 2022, the contents of which are incorporated herein by reference.

### REFERENCE SIGNS LIST

1: flat glass
1a: first main surface
1b: second main surface
1c: light diffusing portion
2: outer frame
3: glass adhesive layer
4: sealing material layer
5: conductive film
6: metal conductor
7: anti-reflective film
10: cover glass with an outer frame

1. A cover glass with an outer frame comprising:
a flat glass having a first main surface and a second main surface that are opposite sides; and
an outer frame bonded to the first main surface of the flat glass via a glass adhesive layer, wherein
the outer frame is made of a glass ceramic in which a filler is dispersed in a borosilicate glass,
the borosilicate glass and the filler both contain aluminum oxide,
the filler has a volume fraction of 40% to 65% in the glass ceramic,
the aluminum oxide contained in the filler has a volume fraction of 10% to 65% in the glass ceramic, and
an absolute value of a difference in average thermal expansion coefficient at 50° C. to 350° C. between the flat glass and the outer frame is 20×10⁻⁷/° C. or less.

2. The cover glass with an outer frame according to claim 1, wherein a surface of the outer frame that is opposite to a surface facing the flat glass has a maximum height roughness Rz of 5 μm or less.

3. The cover glass with an outer frame according to claim 1, wherein
the glass adhesive layer has a softening point lower than a softening point of the borosilicate glass, and
the softening point of the glass adhesive layer is lower than a glass transition point Tg of the flat glass.

4. The cover glass with an outer frame according to claim 3, wherein
the glass adhesive layer comprises a bismuth glass, a vanadium glass, or a borosilicate glass, and
the glass adhesive layer has a thickness of 10 μm to 30 μm.

5. The cover glass with an outer frame according to claim 1, wherein the outer frame has a height of 350 μm to 4 mm.

6. The cover glass with an outer frame according to claim 1, wherein
the flat glass comprises a light diffusing portion on the first main surface, and
the light diffusing portion is formed by directly processing the flat glass.

7. The cover glass with an outer frame according to claim 6, wherein the light diffusing portion is formed inside a region of the flat glass where the outer frame is bonded.

8. The cover glass with an outer frame according to claim 1, wherein
the flat glass comprises a conductive film on the first main surface,
a metal conductor is provided inside the outer frame, the metal conductor penetrating the outer frame and being provided perpendicular to the flat glass, and
the conductive film and the metal conductor are electrically connected to each other.

9. The cover glass with an outer frame according to claim 2, further comprising:
a sealing material layer on the surface of the outer frame that is opposite to a surface facing the flat glass, wherein
the sealing material layer is made of a metal film or a glass frit.

10. The cover glass with an outer frame according to claim 9, wherein
the sealing material layer is made of a metal film, and
the metal film comprises an Ag layer or an Au layer on an outermost surface of the metal film.

11. A semiconductor light emitting device comprising:
the cover glass with an outer frame according to claim 10;
a substrate; and;
a light emitting element provided on the substrate, wherein
the cover glass with an outer frame is integrated with the substrate via the sealing material layer in the cover glass with an outer frame and a gold-tin ring, to hermetically seal the light emitting element.

12. A semiconductor light receiving device comprising:
the cover glass with an outer frame according to claim 10;
a substrate; and;
a light receiving element provided on the substrate, wherein
the cover glass with an outer frame is integrated with the substrate via the sealing material layer in the cover glass with an outer frame and a gold-tin ring, to hermetically seal the light receiving element.
